(19) United States
(12) Patent Application Publication
(10) Pub. No.: US 2009/0321768 A1
(43) Pub. Date: Dec. 31, 2009

(54) LED

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/436,132

(22) Filed: May 6, 2009

(30) Foreign Application Priority Data
Jun. 27, 2008 (CN) 200810068068.8

(51) Int. Cl. H01L 33/00

(52) U.S. Cl. 257/98; 257/E33.059

(57) ABSTRACT

An LED includes a base having a depression, a chip disposed in the depression and an encapsulation received in the depression for encapsulating the chip and a heat sink. The heat sink includes a plurality of fins formed on a top of the base and a heat-conductive material filled in the space between adjacent fins. The heat-conductive material has a plurality of pores therein.

### BACKGROUND

1. Technical Field

The present invention relates to a light emitting diode (LED), and more particularly to an LED incorporating a heat sink for improving a heat dissipation thereof.

2. Description of Related Art

Light emitting diodes (LEDs) are a commonly used light source in applications including lighting, signaling, signage and displays. The LED has several advantages over incandescent and fluorescent lamps, including high brightness, long life, and stable light output.

A conventional LED generally includes a base, a chip mounted on the base, and an encapsulation sealing the chip. When the LED works, about 80% of electric power consumed by the LED is transformed into heat. The heat is then transferred to the base and dissipated to ambient air. However, the heat on the base could not be quickly dissipated to ambient air for a relatively smaller heat exchange area of the base so that the LED may be overheated, significantly reducing work efficiency and service life thereof. Therefore, how to efficiently dissipate the heat of the LED becomes a challenge.

What is needed, therefore, is an LED having a high heat dissipation efficiency.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present LED. Moreover, in the drawings, like reference numerals designate corresponding parts throughout the several views.

FIG. 1 is a cross-sectional view of an LED in accordance with a first embodiment.

FIG. 2 is a cross-sectional view of an LED in accordance with a second embodiment.

### DETAILED DESCRIPTION

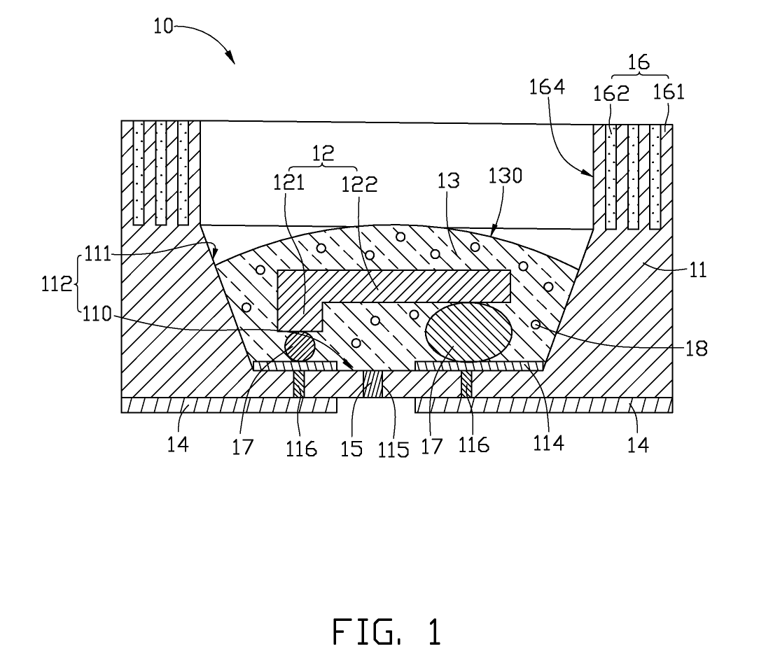

Referring to FIG. 1, an LED 10 in accordance with a first embodiment is illustrated. The LED 10 includes a base 11, a chip 12, an encapsulation 13, two electrodes 14, an electricity-insulated post 15 and a heat sink 16.

The base 11 is made of porcelain having good heat conduction. Alternatively, the base 11 can be made of metal, such as copper or aluminum. The base 11 has a concave configuration with a depression 112 defined in a top portion thereof. The depression 112 has a trapeziform cross section. The base 11 has a flat supporting wall 110 formed at a bottom of the depression 112 and a sidewall 111 expanding upwardly from a periphery of the supporting wall 110. The supporting wall 110 and the side wall 111 cooperatively define the depression 112 so that the depression 112 has a narrow bottom portion and a wide top portion.

The sidewall 111 is spread with a high light reflective material, such as gold or sliver. The base 11 defines a mounting hole 115 vertically extending therethrough from the supporting wall 110 to a bottom surface of the base 11. The mounting hole 115 communicates the depression 112 with an outside below the base 11.

The heat sink 16 is formed on a top of the base 11 and located around the depression 112. The heat sink 16 includes a plurality of fins 161 extending upwardly from a top surface of the base 11 integrally. The fins 161 are spaced from each other in parallel. A heat-conductive material 162 is filled in the spaces between adjacent fins 161. The heat-conductive material 162 has a plurality of pores for accommodating a large amount of air therein and increase heat exchange area with an ambient air.

The chip 12 is disposed in the depression 112, and is a p-n junction structure. The chip 12 includes a thick portion 121 and a thin portion 122 along a horizontal direction. The thick portion 121 has a larger thickness than the thin portion 122. The thick portion 121 and the thin portion 122 are two opposite poles of the chip 12. A top surface of the thin portion 122 is coplanar with a top surface of the thick portion 121, and a bottom surface of the thin portion 122 is higher than a bottom surface of the thick portion 121. Thus, the chip 12 has a flat top surface and a step-shape bottom surface.

Two electrode layers 114 are spread on the supporting wall 110 respectively corresponding to the thick portion 121 and the thin portion 122 of the chip 12. The thick portion 121 and the thin portion 122 of the chip 12 are electrically connected with the electrode layers 114 respectively by two soldering nubs 17. The soldering nubs 17 are solder balls, which are heat-conductive and electricity-conductive. The soldering nubs 17 are located between the chip 12 and the electrode layers 114 so as to support the chip 12. The mounting hole 115 is located under the thin portion 122 of the chip 12 and between the soldering nubs 17.

The encapsulation 13 is received in the depression 112 of the base 11 for encapsulating the chip 12 for protecting the chip 12 from external physical shock. The encapsulation 13 is made of a light penetrable material, such as acryl, silicone or epoxy resin. The encapsulation 13 is uniformly mixed with fluorescent powder 18 so as to turn light emitted by the chip 12 into required light according to actual need.

The encapsulation 13 has a curved, convex top surface 130. The top surface 130 is below the heat sink 16 in a vertical direction. The top surface 130 of the encapsulation 13 is used to converge light emitted by the chip 12 so as to enable the light generated by the LED 10 to be a spot light. An inside fin 161 adjacent to the depression 112 has a lateral surface 164 facing the depression 112. The lateral surface 164 can be made to have a smooth surface and be spread with a high light reflective material so that the light incident on the lateral surface 164 can be reflected to the outside of the LED 10.

The electrodes 14 are attached to the bottom surface of the base 11. Two electric poles 116, which respectively connect to the electrodes 14, vertically extend through the base 11 to electrically connect with the electrode layers 114 respectively. Thus, the electrodes 14 electrically connect with the thin portion 122 and the thick portion 121 of the chip 12 respectively, via the electric poles 116, the electrode layers 114 and the soldering nubs 17. The electric poles 116 each have an electrical conductivity higher than that of the base 11. The electric poles 116 can be made of a material selected from a group consisting of metal, compound having metal, resin and graphite, or compound having graphite and resin.

The electricity-insulated post 15 is located in a middle of the base 11 and between the electric poles 116. The electricity-insulated post 15 is received in the mounting hole 115. The electricity-insulated post 15 is made of a heat-conductive and electricity-insulated material, such as alumina or porcelain, which has a heat conductivity higher than that of the base 11. Therefore, the heat exchange efficiency of the electricity-insulated post 15 can be higher than that of the base 11. The electricity-insulated post 15 includes a plurality of pores therein which can accommodate a large amount of air therein to increase a heat exchange area of the electricity-insulated post 15 with the ambient air, thereby to enhance a heat exchange efficiency of the electricity-insulated post 15.

In operation, the heat generated by the chip 12 is transferred to the base 11 via the soldering nubs 17, the electrode layer 114 and via the encapsulation 13. Then part of the heat is conducted downwardly via the electric poles 116, the electricity-insulated post 15 and a bottom portion of the base 11. Another part of the heat is upwardly transferred to the heat sink 16 via lateral portions of the base 11. Finally the heat is dissipated to ambient air via the fins 161 and the heat-conductive material 162.

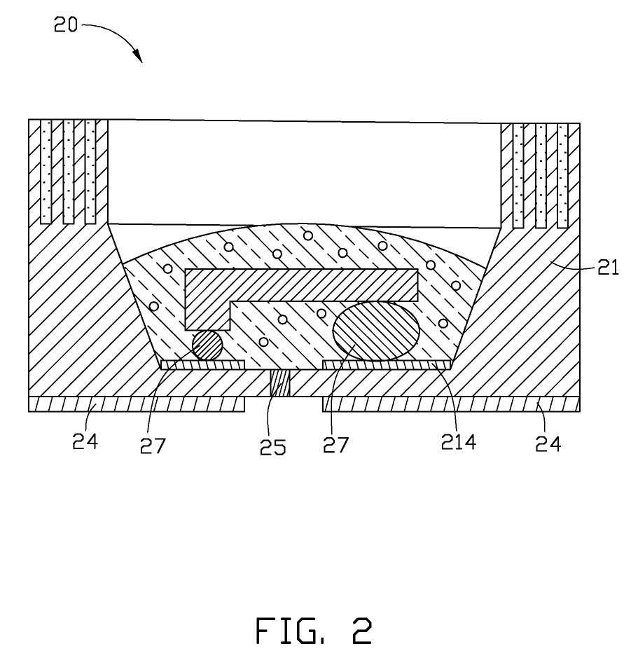

Referring to FIG. 2, an LED 20 according to a second embodiment is shown. The LED 20 has a configuration similar to the LED 10. The base 21 is made of metal. The electrodes 24 connect with the electrode layers 214 and the soldering nubs 27 via the base 21 so as to omit the electric poles 116. The electricity-insulated post 25 horizontally extends through the base 21 so that the base 21 is divided into two spaced portions respectively located at left and right thereof by the electricity-insulated post 25.

It is to be understood, however, that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An LED comprising:
a base including a depression defined in a top surface thereof,
a chip disposed in the depression;
an encapsulation received in the depression for encapsulating the chip; and
a heat sink comprising a plurality of fins formed on a top of the base and a heat-conductive material filled in the space between adjacent fins, the heat-conductive material having a plurality of pores therein.

2. The LED of claim 1, wherein the depression is defined in a middle of the base, and the fins of the heat sink integrally extend from lateral portions of the base around the depression.

3. The LED of claim 2, wherein the fins adjacent to the depression each include a smooth lateral surface facing the depression, the smooth lateral surface being coated with a high light reflective material.

4. The LED of claim 1, wherein the encapsulation includes a curved, convex top surface, and the top surface of the encapsulation is below the heat sink in a vertical direction.

5. The LED of claim 1, wherein the base is made of porcelain, and two spaced electrodes are attached to a bottom surface of the base, and two electric poles, which respectively connecting to the electrodes, extend through the base to electrically connect with the chip.

6. The LED of claim 5, wherein the electric poles each have a thermal conductivity higher than that of the base.

7. The LED of claim 6, wherein the electric poles are made of a material selected from a group consisting of metal, compound having metal, resin and graphite or compound having graphite and resin.

8. The LED of claim 1, wherein the base is made of metal, and an electricity-insulated post horizontally extends through the base so that the base is divided into two spaced portions respectively located at left and right of the electricity-insulated post.

9. The LED of claim 8, wherein the electricity-insulated post is made of a heat-conductive material, and includes a plurality pores therein.

10. The LED of claim 1, wherein the chip includes a thin portion and a thick portion, the thick portion has a thickness larger than the thin portion, the thick portion and the thin portion of the chip are electrically connected with two electrode layers in a bottom of the depression by two soldering nubs respectively, the soldering nubs are located between the chip and the electrode layers so as to support the chip.

11. An LED comprising:
a base including a depression defined in a middle portion thereof,
a chip disposed in the depression;
an encapsulation received in the depression for encapsulating the chip; and
a heat sink formed on tops of lateral portions of the base around the depression.

12. The LED of claim 11, wherein the heat sink comprises a plurality of fins integrally from the base and a heat-conductive material filled in a space between adjacent fins, the heat-conductive material having a plurality of pores therein.

13. The LED of claim 12, wherein the fins adjacent to the depression each include a smooth lateral surface facing the depression, the smooth lateral surface being coated with a high light reflective material.

14. The LED of claim 11, wherein the encapsulation includes a curved, convex top surface, and the top surface of the encapsulation is below the heat sink in a vertical direction.
